(19) United States
(12) Patent Application Publication
(10) Pub. No.: US 2014/0103523 A1
(43) Pub. Date: Apr. 17, 2014

(54) SEMICONDUCTOR PACKAGE

(71) Applicant: Samsung Electronics Co., Ltd., Suwon-si (KR)

(72) Inventors: Jae-gwon JANG, Hwaseong-si (KR); Young-lyong KIM, Gunpo-si (KR); Jin-woo PARK, Seoul (KR); Ae-nee JANG, Seoul (KR)

(73) Assignee: SAMSUNG ELECTRONICS CO., LTD., Suwon-Si (KR)

(21) Appl. No.: 14/045,881

(22) Filed: Oct. 4, 2013

(30) Foreign Application Priority Data
Oct. 16, 2012 (KR) 10-2012-0115036

(51) Int. Cl. H01L 23/498

(52) U.S. Cl. CPC H01L 23/49838; H01L 23/49811
USPC 257/737; 257/777

(57) ABSTRACT

A semiconductor package including a lower semiconductor chip, and an upper semiconductor chip flip-chip bonded on the lower semiconductor chip may be provided. Each of the lower and upper semiconductor chips includes a first bonding pad formed on an active surface, which has a center line extending in a first direction, and a first rewire electrically connected to the first bonding pad, The first rewire includes first and second connection regions. The first and second connection regions face each other and are disposed at a same distance from the center line in a second direction, which is perpendicular to the first direction.

### CROSS-REFERENCE TO RELATED APPLICATIONS

This application claims priority under 35 U.S.C. §119 to the benefit of Korean Patent Application No. 10-2012-0115036, filed on Oct. 16, 2012, in the Korean Intellectual Property Office, the disclosure of which is incorporated herein in its entirety by reference.

### BACKGROUND

The inventive concepts relate to a semiconductor package, and more particularly, to a semiconductor package including stacked mirror-type semiconductors. Although electronic products have become smaller, the amount of data that they are required to process has increased. Accordingly, due to a continuing demand for increasing the degree of integration of semiconductor devices used for such electronic products, methods for stacking a plurality of semiconductor chips have been suggested. However, if a plurality of chips are stacked to increase the degree of integration, misalignment may occur during an electrical connection between the semiconductor chips, or between a plurality of different wafers used to manufacture semiconductor chips for a semiconductor package.

### SUMMARY

The inventive concepts provide a semiconductor package including a mirror-type semiconductor chip in one wafer.

According to an example embodiment, a semiconductor package includes a lower semiconductor chip, and an upper semiconductor chip flip-chip bonded on the lower semiconductor chip. Each of the lower and upper semiconductor chips includes a first bonding pad formed on an active surface having a center line extending in a first direction, and a first rewire electrically connected to the first bonding pad and including first and second connection regions. The first and second connection regions face each other and are disposed at a same distance from the center line in a second direction, which is perpendicular to the first direction.

The first connection region and the second connection region of the lower semiconductor chip may respectively face the second connection region and the first connection region of the upper semiconductor chip, and may be respectively electrically connected to each other through a bump.

The lower and upper semiconductor chips may further include a second bonding pad formed on the active surface, and a second rewire electrically connected to the second bonding pad and including third and fourth connection regions. The third and fourth connection regions may face each other and may be disposed at a same distance from the center line in the second direction. The first to fourth connection regions may be spaced apart from each other in the second direction.

The lower semiconductor chip may further include a third bonding pad which is electrically connected to the substrate through a bonding wire.

The first connection region and the second connection region of the lower semiconductor chip may respectively face the second connection region and the first connection region of the upper semiconductor chip, and the third connection region and the fourth connection region of the lower semiconductor chip may respectively face the fourth connection region and the third connection region of the upper semiconductor chip.

The semiconductor package may further include first to fourth bumps respectively formed on the first to fourth connection regions of the lower semiconductor chip. The first and second bumps respectively may contact the second and first connection regions of the upper semiconductor chip; and the third and fourth bumps respectively may contact the fourth and third connection regions of the upper semiconductor chip.

The semiconductor package may further include first and second bumps respectively formed on the first and third connection regions of the lower semiconductor chip, and third and fourth bumps respectively formed on the first and third connection regions of the upper semiconductor chip. The first and second bumps may respectively contact the second and fourth connection regions of the upper semiconductor chip, and the third and fourth bumps respectively may respectively contact the second and fourth connection regions of the lower semiconductor chip.

The semiconductor package may further include first to fourth bumps respectively formed on the first to fourth connection regions of the lower semiconductor chip, and fifth to eighth bumps respectively formed on the first to fourth connection regions of the upper semiconductor chip. The first, second, third, and fourth bumps respectively may contact the sixth, fifth, eighth, and seventh bumps, respectively.

According to an example embodiment, a semiconductor chip includes a first bonding pad formed on an active surface having a center line extending in a first direction, and a first rewire electrically connected to the first bonding pad and including first and second connection regions. The first and second connection regions face each other and are disposed at a same distance from the center line in a second direction, which is perpendicular to the first direction.

The semiconductor chip may further include a bump formed at at least one of the first connection region and the second connection region.

The first bonding pad may be disposed on the center line of the active surface.

The first bonding pad may be spaced a desired (alternatively, predetermined) distance apart from the center line of the active surface.

The semiconductor chip may further include a second bonding pad formed on the active surface, and a second rewire electrically connected to the second bonding pad and including third and fourth connection regions. The third and fourth connection regions may face each other and may be disposed at a same distance from the center line in the second direction. The first to fourth connection regions may be spaced apart from each other in the second direction.

The semiconductor chip may further include a bump formed at at least one of the third connection region and the fourth connection region.

The semiconductor chip may further include a third bonding pad that is formed on the active surface and the third bonding pad may be electrically connected to a substrate.

According to an example embodiment, a semiconductor package includes a first semiconductor chip on a substrate, a second semiconductor chip flip-chip bonded on the first semiconductor chip, and a plurality of connection structures. Each of the first and second semiconductor chips includes at least one first bonding pad provided in a first direction, and at least one first rewire extending from the at least one first bonding pad in a second direction, the second direction being perpendicular to the first direction, the at least one first rewire having first and second connection regions, the first and second connection regions being opposite to each other and being at a first distance with respect to a center line of the semiconductor chip, the center line defined in the first direction. The plurality of connection structures is on at least one of the connection regions and is configured to electrically connect the second semiconductor chip to the first semiconductor chip.

The connection structures may be provided on the first and second connection regions of both of the first and second semiconductor chips.

The connection structures may be provided on one of the first and second connection regions of the first and second semiconductor chips.

The connection structures may be provided on the first and second connection regions of one of the first and second semiconductor chips.

The at least one first bonding pad may be arranged off-axis from the center line.

The first and second semiconductor chips may further include at least one second bonding pad provided in the first direction, each of the at least one second bonding pad paired with a corresponding first bonding pad, and at least one second rewire extending from the at least one bonding pad in the second direction, the at least one rewire having a third and a fourth connection regions, the third and fourth connection regions being opposite to each other and being at a second distance with respect to the center line.

### BRIEF DESCRIPTION OF THE DRAWINGS

Example embodiments of the inventive concepts will be more clearly understood from the following detailed description taken in conjunction with the accompanying drawings in which:

FIG. 1 is a cross-sectional view of a semiconductor package according to an example embodiment;

FIG. 2 is a plan view illustrating an active surface of a first semiconductor chip according to an example embodiment;

FIG. 3 illustrates flip-chip bonding of two first semiconductor chips of FIG. 2 together;

FIG. 4 is a plan view illustrating an active surface of a first semiconductor chip according to an example embodiment;

FIG. 5 illustrates flip-chip bonding of a first semiconductor chip and a second semiconductor chip according to an example embodiment;

FIG. 6 is a cross-sectional view of a semiconductor package according to an example embodiment;

FIG. 7 shows flip-chip bonding between a first semiconductor chip and a second semiconductor chip according to an example embodiment;

FIG. 8 is a cross-sectional view of a semiconductor package according to an example embodiment;

FIG. 9 shows flip-chip bonding between a first semiconductor chip and a second semiconductor chip of FIG. 8;

FIG. 10 is a cross-sectional view of a semiconductor package according to an example embodiment;

FIG. 11 is a cross-sectional view of a semiconductor package according to an example embodiment;

FIG. 12 is a plan view illustrating an active surface of a first semiconductor chip according to an example embodiment;

FIG. 13 shows flip-chip bonding of two semiconductor chips of FIG. 12 together;

FIG. 14 is a plan view illustrating an active surface of a first semiconductor chip according to an example embodiment;

FIG. 15 shows flip-chip bonding between a first semiconductor and a second semiconductor chip according to an example embodiment;

FIG. 16 shows flip-chip bonding between a first semiconductor chip and a second semiconductor chip according to an example embodiment;

FIG. 17 is a block diagram illustrating a memory card including a semiconductor package according to an example embodiment; and

FIG. 18 is a view illustrating a system according to an example embodiment.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity.

### DETAILED DESCRIPTION

Hereinafter, example embodiments will be described in more detail with reference to the accompanying drawings. However, embodiments of the present inventive concepts may be embodied in many different forms and should not be construed as being limited to the embodiments set forth herein. These embodiments are provided so that this disclosure will be thorough and complete, and will fully convey the concept of the present inventive concepts to those skilled in the art. Like reference numerals refer to like elements throughout. Furthermore, various elements and regions are drawn schematically in the drawings. Accordingly, the inventive concepts are not limited to relative sizes or intervals in the accompanying drawings.

Although terms like first and second may be used to describe various components, the components are not limited to the terms. These terms are only used to distinguish one component from another component. For example, a first component may be referred to as a second component and vice versa, without departing from the scope of the present inventive concepts.

The terms used in this specification are for describing specific embodiments, and are not intended to limit the scope of the present inventive concepts. Terms in the singular form may include the plural form unless described otherwise. The meaning of the terms “include,” “comprise,” “including,” and “comprising,” specifies a property, a region, a fixed number, a step, a process, an element and/or a component but does not exclude other properties, regions, fixed numbers, steps, processes, elements and/or components.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical terms and scientific terms) used herein have the same meanings as commonly understood by one of ordinary skill in the art. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

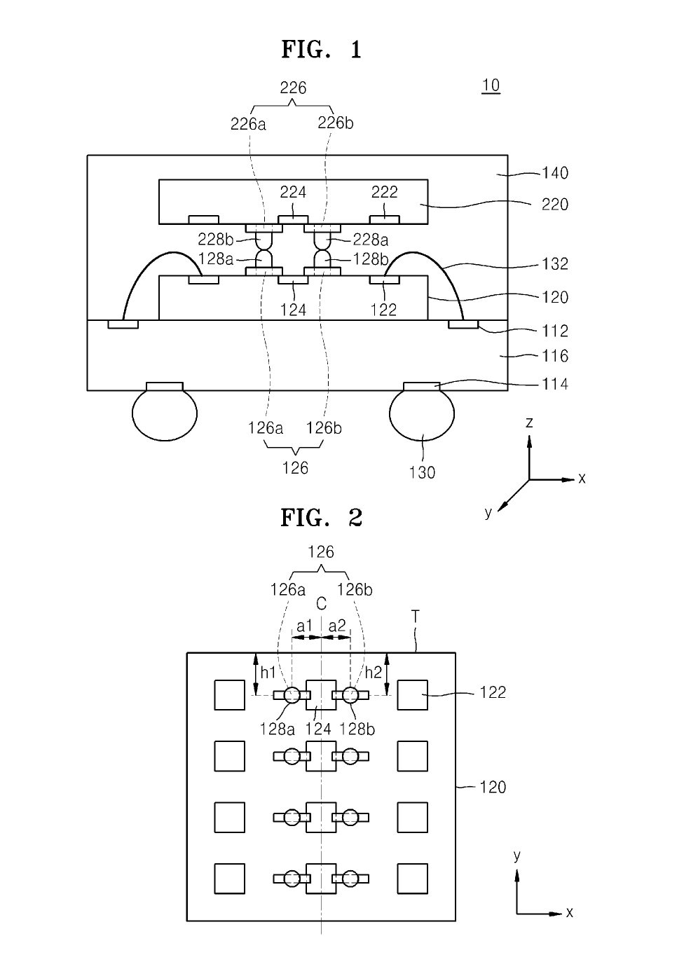

FIG. 1 is a cross-sectional view of a semiconductor package 100 according to an example embodiment.

Referring to FIG. 1, the semiconductor package 10 may include a first semiconductor chip 120 mounted on a substrate 116, a second semiconductor chip 220 flip-chip bonded on the first semiconductor chip 120 to have active surfaces facing each other, a plurality of first bumps 128 (which includes first bumps 128a and 128b) and a plurality of second bumps 228 (which includes second bumps 228a and 228b) for electrically connecting the first semiconductor chip 120 to the second semiconductor chip 220, and a bonding wire 132 for electrically connecting the first semiconductor chip 120 to the substrate 116.

Further, the semiconductor package 10 may be sealed by a sealing material 140 for protection from an external shock, temperature, humidity, etc.

The sealing material 140 may be formed of a polymer such as a resin. For example, the sealing material 140 may be an epoxy molding compound (EMC) but is not limited thereto. The sealing material 140 may seal the lateral surface and top surface of the first and second semiconductor chips 120 and 220.

The substrate 116 may include a conductive circuit on an insulating substrate and may be a rigid printed circuit board, a flexible printed circuit board (FPCB), or a tape board. However, the substrate 116 is not limited thereto.

The first and second semiconductor chips 120 and 220 may be memory chips. The memory chip may be DRAM, SRAM, flash, PRAM, ReRAM, FeRAM, or MRAM. However, the memory chip is not limited thereto.

The first semiconductor chip 120 may include a first bonding pad 124 on an active surface with the center line extending in a first direction y, a first rewire 126 including first and second connection regions 126a and 126b electrically connected to the first bonding pad 124, each disposed at a same distance from the center line to face each other in a second direction x (which is perpendicular to the first direction y), the first bumps 128a and 128b respectively formed at the first and second connection regions 126a and 126b, and a second bonding pad 122 electrically connected to the substrate 116.

The first bonding pad 124 may have an electrical access path that extends through the first rewire 126, and the first semiconductor chip 120 may be electrically connected to the second semiconductor chip 220 through the first bumps 128a and 128b respectively disposed at the first and second connection regions 126a and 126b of the first rewire 126.

The second semiconductor chip 220 may include a third bonding pad 224 on an active surface of the second semiconductor chip 220 with the center line extending in the first direction y, a second rewire 226 including third and fourth connection regions 226a and 226b electrically connected to the third bonding pad 224, each disposed at a same distance from the center line to face each other in the second direction x (which is perpendicular to the first direction y), the second bumps 228a and 228b respectively formed at the third and fourth connection regions 226a and 226b, and a fourth bonding pad 222.

Referring to FIG. 1, the second bonding pad 122 of the first semiconductor chip 120 may be electrically connected to the substrate 116. Alternatively, in the event that the second semiconductor chip 220 is first mounted on the substrate 116 and the first semiconductor chip 120 is flip-chip bonded on the second semiconductor chip 220, the fourth bonding pad 222 may be electrically connected to the substrate 116 through wire bonding.

The third bonding pad 224 may have an electrical access path that extends through the second rewire 226, and the second bumps 228a and 228b respectively disposed at the third and fourth connection regions 226a and 226b of the second rewire 226 may be respectively connected to the first bumps 128b and 128a of the first semiconductor chip 120.

The first and second semiconductor chips 120 and 220 may be separated from a wafer (which is formed through a same semiconductor process) by using a singulation process.

The active surfaces of the first and second semiconductor chips 120 and 220 are coupled to face each other through flip-chip bonding processes. Because each of the active surfaces is of a mirror type, the first and second semiconductor chips 120 and 220 separated from the same wafer may be used to form the semiconductor package 10.

An adhesive layer (not shown) for attaching the first semiconductor chip 120 to the substrate 116 may be further provided between the inactive surface of the first semiconductor chip 120 and the top surface of the substrate 116. The adhesive layer may include a non-conductive film (NCF), an anisotropic conductive film (ACF), a UV-sensitive film, an instant adhesive, a thermosetting adhesive, a laser-curable adhesive, an ultrasonic-curable adhesive, and a non-conductive paste (NCP). However, the adhesive layer is not limited thereto.

A substrate bonding pad 112 on the top surface of the substrate 116 may be electrically connected to the bump pad 114 at the bottom surface through a circuit, and the bump pad 114 at the bottom surface may be connected to the solder bump 130 that is to be connected to an external device, for example.

Further, when the first and second bumps 128a, 128b, 228a, and 228b at each active surface electrically connects the first semiconductor chips 120 to the second semiconductor chip 220, the interval between the first and second semiconductor chips 120 and 220 may be controlled by adjusting the heights of the first and second bumps 128a, 128b, 228a, and 228b.

Accordingly, when the bonding wire 132 electrically connecting the substrate 116 to the first semiconductor chip 120 is formed and the second semiconductor chip 220 is mounted on the first semiconductor chip 120 through a flip-chip bonding method, disconnection caused by a physical contact between the bonding wire 132 and the active surface of the second semiconductor chip 220 may be reduced or prevented from occurring.

According to this example embodiment, an integrated circuit is formed on a semiconductor wafer (not shown) such that individual chip sections are formed to have mirror-type rewires and bumps, and the semiconductor wafers are divided into individual chips. As a result, when assembling a semiconductor package, the first and second semiconductor chips 120 and 220 may be used as they are, thereby reducing manufacturing costs and processing times.

FIG. 2 is a plan view illustrating an active surface of the first semiconductor chip 120 according to an example embodiment. Because each of the active surfaces of the first semiconductor chip 120 and the second semiconductor chip 220 shown in FIG. 1 is of a mirror type, the plan view illustrating the active surface of the second semiconductor chip 220 is omitted.

Referring to FIG. 2, the first bonding pad 124 may be provided on the active surface of the first semiconductor chip 120 with the defined center line C extending in the first direction y of the first semiconductor chip 120, the first rewire 126 including the first and second connection regions 126a and 126b and electrically connected to the first bonding pad 124, each of the first and second connection regions 126a and 126b being disposed at the same distance from the center line C and facing each other in the second direction x (which is perpendicular to the first direction y), the first bumps 128a and 128b respectively formed at the first and second connection regions 126a and 126b, and the second bonding pad 122 formed at the edge of the active surface.

The first bonding pad 124 may be electrically connected to another semiconductor chip through the first rewire 126 and the first bumps 128a and 128b. Additionally, the second bonding pad 122 may be electrically connected to a substrate through a connection member such as a bonding wire. However, the second bonding pad 122 is not limited thereto.

The distances from the center line C to each of the first bumps 128a and bump 128b may be the same, that is, a1=a2, and the distances from the upper T of the first semiconductor chip 120 to each of the first bumps 128a and bump 128b may be the same. For instance, the distances from the upper T of the first semiconductor chip 120 to a frontmost one of the first bump 128a and to a corresponding first bump 128b may be the same, that is, h1=h2.

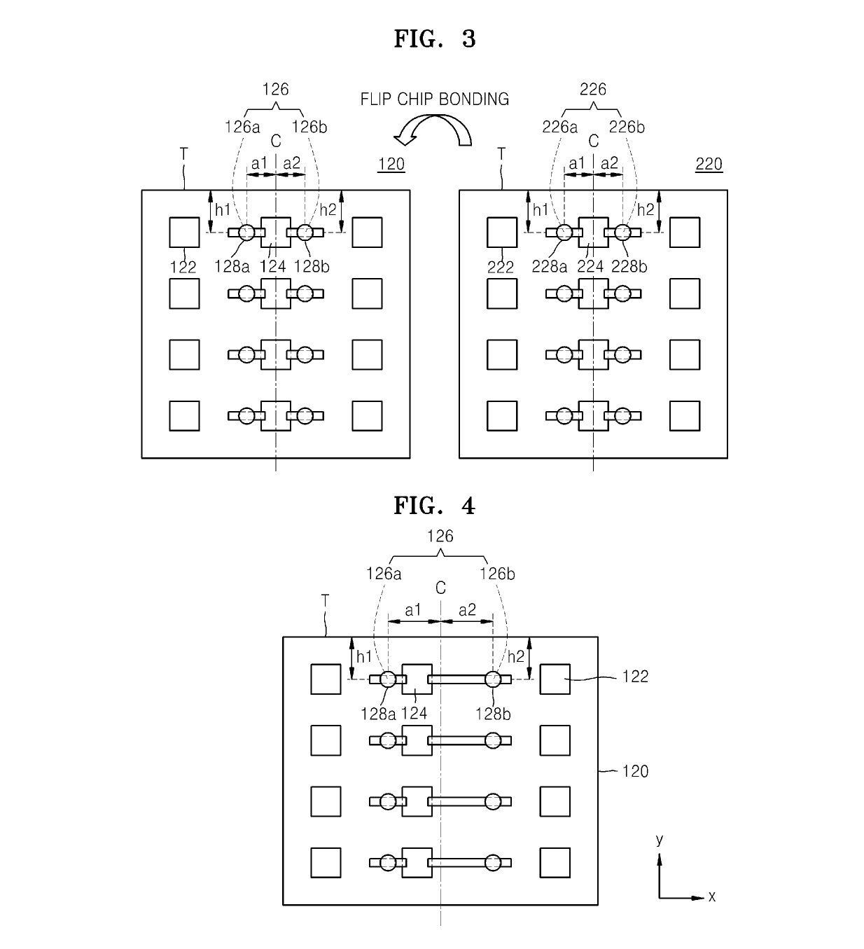

Because the first rewire 126 including the first and second connection regions 126a and 126b may be disposed at the above-mentioned position, a mirror-type semiconductor package may be implemented by using a plurality of semiconductor chips separated from a same wafer. This will be described with reference to FIG. 3.

FIG. 3 shows flip-chip bonding of two first semiconductor chips 120 of FIG. 2 together. In FIG. 3, the first semiconductor chip 120 has a same structure as the second semiconductor chip 220. For example, the first and third bonding pads 124 and 224, the first and second rewires 126 and 226, and the first and second bumps 128a, 128b, 228a, and 228b may be respectively formed at the same positions as described above with reference to FIG. 2.

Referring to FIG. 3, the first bumps 128a and 128b of the first semiconductor chip 120 may be respectively connected to the second bumps 228b and 228a of the second semiconductor chip 220 through a flip-chip bonding method.

As mentioned above, the first and second rewires 126 and 226 extending from the first and third bonding pads 124 and 224 may be formed, and the first and second bumps 128a, 128b, 228a, and 228b may be formed on the first to fourth connection regions 126a, 126b, 226a, and 226b of the first and second rewires 126 and 226, thereby forming a mirror-type semiconductor package through flip-chip bonding of the first semiconductor chip 120 and the second semiconductor chip 220.

FIG. 4 is a plan view illustrating an active surface of a first semiconductor chip according to an example embodiment. Compared to FIG. 2, the first bonding pad 124 of the first semiconductor chip 120 may be disposed toward the left and may be spaced a desired (alternatively, predetermined) distance apart from the center line C extending in the first direction y.

Referring to FIG. 4, even when the first bonding pad 124 is spaced a desired (alternatively, predetermined) distance apart from the center line C of the active surface of the first semiconductor chip 120, a mirror-type semiconductor chip may be manufactured by controlling the position of the first rewire 126 including the first and second connection regions 126a and 126b.

For example, the distances from the center line C to each of the first bumps 128a and 128b are the same, that is, a1=a2, and the distances from the upper T of the first semiconductor chip 120, for instance, to a frontmost one of the first bump 128a and to a corresponding first bump 128b may be the same, that is, h1=h2.

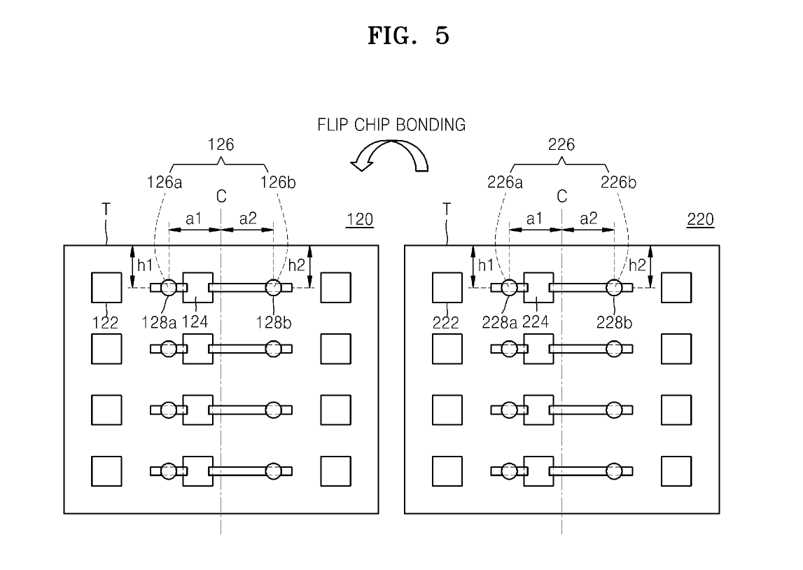

FIG. 5 shows flip-chip bonding of two semiconductor chips of FIG. 4 according to an example embodiment. In FIG. 5, the first semiconductor chip 120 has the same structure as the second semiconductor chip 220. That is, the first and third bonding pads 124 and 224 and the first and second rewires 126 and 226 are respectively formed at the same positions in the first and second semiconductor chips 120 and 220 as described above with reference to FIG. 4.

Referring to FIG. 5, the first bump 128a of the first semiconductor chip 120 may be formed in the first connection region 126a of the first rewire 126, and the first bump 128b of the first semiconductor chip 120 may be formed in the second connection region 126b.

Further, the second bump 228a of the second semiconductor chip 220 may be formed in the third connection region 226a of the second rewire 226, and the fourth bump 228b of the second semiconductor chip 220 may be formed in the fourth connection region 226b.

The first and second semiconductor chips 120 and 220 may be flip-chip bonded to each other, so that the first bump 128a of the first semiconductor chip 120 may contact the second bump 228b of the second semiconductor chip 220, and the first bump 128b of the first semiconductor chip 120 contacts the second bump 228a of the second semiconductor chip 220.

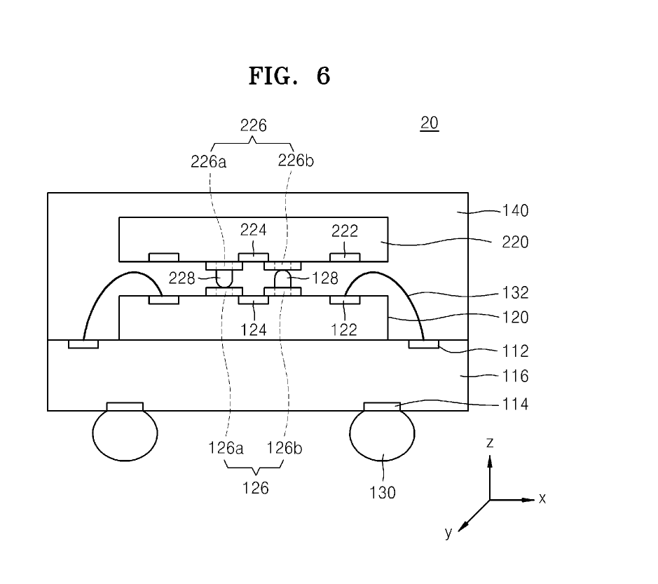

FIG. 6 is a cross-sectional view of a semiconductor package 20 according to an example embodiment. Like reference numerals in FIGS. 1 and 6 indicate like elements, and accordingly, overlapping descriptions are omitted. Compared to FIG. 1, the semiconductor package 20 of FIG. 6 is different in the arrangement of the first and second bumps 128 and 228, which electrically connect the first semiconductor chip 120 to the second semiconductor chip 220.

Referring to FIG. 6, the first semiconductor chip 120 may be electrically connected to the second semiconductor chip 220 through the first and second bumps 128 and 228.

The first bumps 128 of the first semiconductor chip 120 may be formed in the second connection region 126b of the first rewire 126, and the second bumps 228 may be formed in the second connection region 226b of the second rewire 226.

Some of the first bumps 128 of the first semiconductor chip 120 may be directly connected to the second rewire 226 of the second semiconductor chip 220, and some of the second bumps 228 of the second semiconductor chip 220 may be directly connected to the first rewire 126 of the first semiconductor chip 120.

Accordingly, each of the first and second semiconductor chips 120 and 220 may be connected using either one of the bumps 128 and 228. Thus, an interval between the first semiconductor chip 120 and the second semiconductor chip 220 may be reduced.

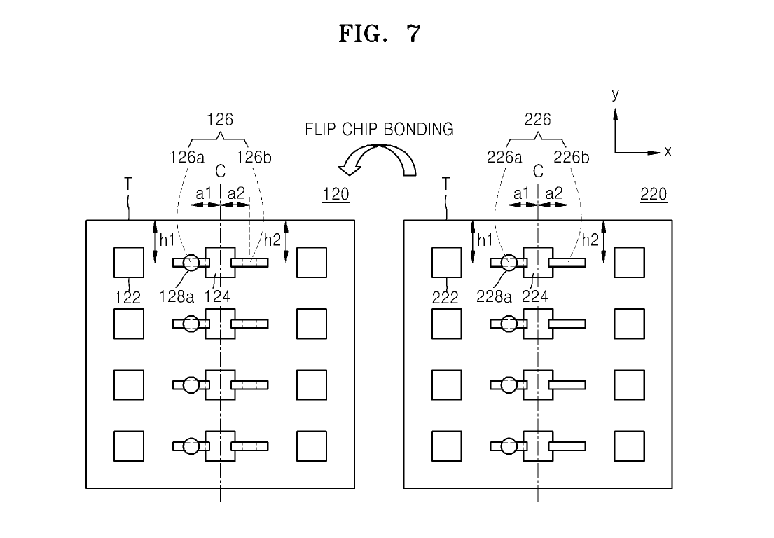

FIG. 7 shows bonding between a first semiconductor chip and a second semiconductor chip according to an example embodiment. In FIG. 7, the first semiconductor chip 120 has the same structure as the second semiconductor chip 220. For example, the first and third bonding pads 124 and 224 and the first and second rewires 126 and 226 may be respectively formed at the same positions in the first and second semiconductor chips 120 and 220 as described above with reference to FIG. 6.

Referring to FIG. 7, the first bumps 128 of the first semiconductor chip 120 may be formed in the first connection region 126a of the first rewire 126.

Additionally, the second bumps 228 of the second semiconductor chip 220 may be formed in the third connection region 226a of the second rewire 226.

The first and second semiconductor chips 120 and 220 may be flip-chip bonded to each other. Also, the first bumps 128 of the first semiconductor chip 120 may contact the fourth connection region 226b of the second rewire 226 in the second semiconductor chip 220.

Additionally, the second bumps 228 of the second semiconductor chip 220 may contact the second connection region 126b of the first rewire 126 in the first semiconductor chip 120.

Accordingly, the first and second semiconductor chips 120 and 220 may be electrically connected to each other by using the first bumps 128 at some positions and the second bumps 228 at the other positions, thereby resulting in one bump layer in effect.

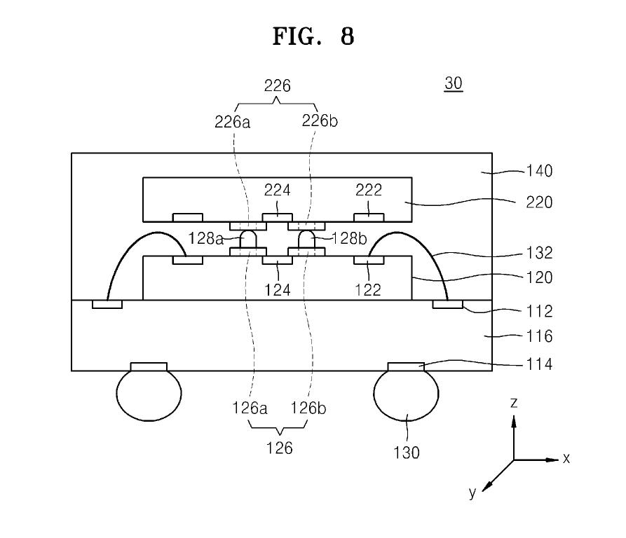

FIG. 8 is a cross-sectional view of a semiconductor package 30 according to an example embodiment. Like reference numerals in FIGS. 6 and 8 indicate like elements, and accordingly, overlapping descriptions are omitted. Compared to FIG. 6, the semiconductor package 30 of FIG. 8 is different in the arrangement of the first and second bumps 128 and 228 electrically connecting the first semiconductor chip 120 and the second semiconductor chip 220.

Referring to FIG. 8, the first semiconductor chip 120 may be electrically connected to the second semiconductor chip 220 through the first bumps 128 on the first rewire 126 of the first semiconductor chip 120.

The first semiconductor chip 120 may include the first bumps 128 having one set of first bumps 128a on the first connection region 126a of the first rewire 126 and another set of first bumps 128b on the second connection region 126b. The first bumps 128a and 128b may be directly connected to the second rewire 226 of the second semiconductor chip 220.

Additionally, although it is described that the first bumps 128 on the first rewire 126 of the first semiconductor chip 120 may be connected to the second rewire 226 of the second semiconductor chip 220, the present inventive concepts are not limited thereto. For example, the second bumps 228 at the second rewire 226 of the second semiconductor chip 220 may be directly connected to the first rewire 126 of the first semiconductor chip 120.

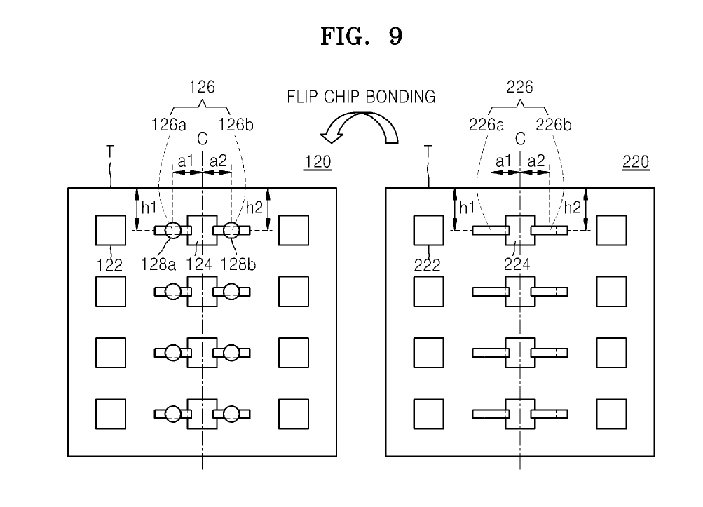

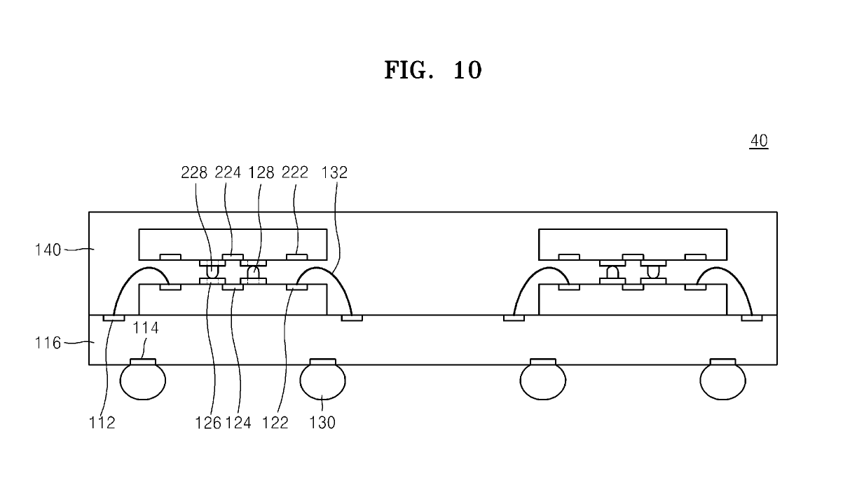

FIG. 9 shows flip-chip bonding between the first semiconductor chip 120 and the second semiconductor chip 220 of FIG. 8. In FIG. 9, the first semiconductor chip 120 has a different structure than the second semiconductor chip 220. For example, the first and third bonding pads 124 and 224 and the first and second rewires 126 and 226 may be respectively formed at the same positions in the first and second semiconductor chips 120 and 220. Because this is described above with reference to FIG. 8, their descriptions are omitted.

Referring to FIG. 9, the first bumps 128a and 128b may be respectively formed in the first and second connection regions 126a and 126b of the first rewire 126 in the first semiconductor chip 120.

Further, no bump may be formed on the second rewire 226 of the second semiconductor chip 220.

The first and second semiconductor chips 120 and 220 may be flip-chip bonded to each other. Also, the first bumps 128a and 128b of the first semiconductor chip 120 may respectively contact the fourth and third connection regions 226b and 226a of the second rewire 226 in the second semiconductor chip 220.

FIG. 10 is a cross-sectional view of a semiconductor package 40 according to an example embodiment. Like reference numerals in FIGS. 8 and 10 indicate like elements, and accordingly, overlapping descriptions are omitted.

Referring to FIG. 10, the semiconductor package 40 may include a plurality of first and second semiconductor chips 120 and 220 electrically connected through flip-chip bonding. Additionally, although it is shown in FIG. 10 that two first semiconductor chips 120 are mounted on the substrate 116 such that the second semiconductor chip 220 is flip-chip bonded on the first semiconductor chip 120, the present inventive concepts are limited thereto. For example, more than two first semiconductor chips 120 may be mounted on the substrate 106.

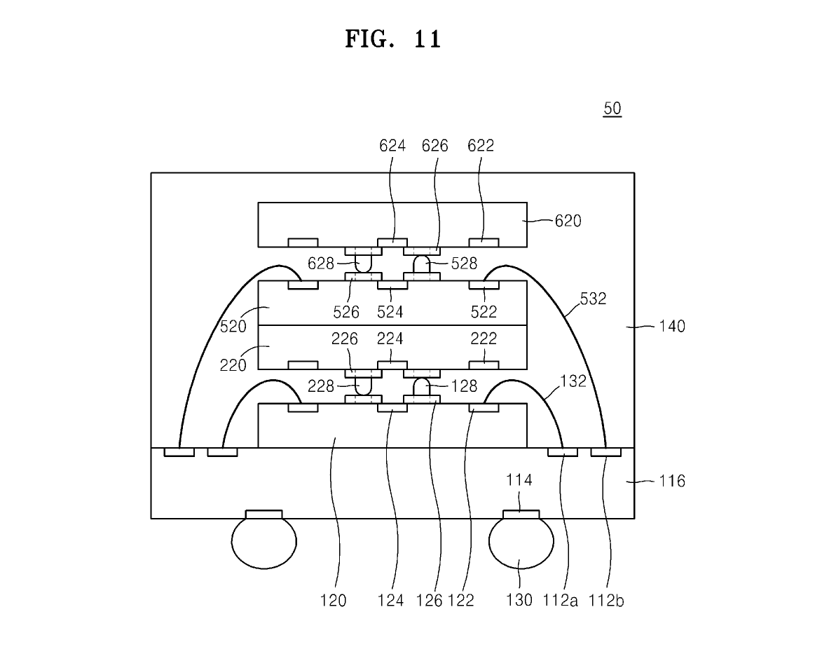

FIG. 11 is a cross-sectional view of a semiconductor package 50 according to an example embodiment. Like reference numerals in FIGS. 8 and 11 indicate like elements, and accordingly, overlapping descriptions are omitted.

Referring to FIG. 11, the semiconductor package 50 may include a first semiconductor chip 120, a second semiconductor chip 220 flip-chip bonded and mounted on the first semiconductor chip 120, a third semiconductor chip 520 mounted on the second semiconductor chip 220, and a fourth semiconductor chip 620 flip-chip bonded and mounted on the third semiconductor chip 520.

An adhesive layer (not shown) for attaching the third semiconductor chip 520 to the second semiconductor chip 220 may be further provided between the inactive surface of the third semiconductor chip 520 and the top surface of the second semiconductor chip 220. The adhesive layer may include an NCF, an ACF, a UV-sensitive film, an instant adhesive, a thermosetting adhesive, a laser-curable adhesive, an ultrasonic-curable adhesive, and an NCP. However, the adhesive layer is not limited thereto.

The first semiconductor chip 120 may be electrically connected to a first substrate bonding pad 112a of the substrate 116 by using the bonding wire 132, and the third semiconductor chip 520 may be electrically connected to a second substrate bonding pad 112b by using a bonding wire 532.

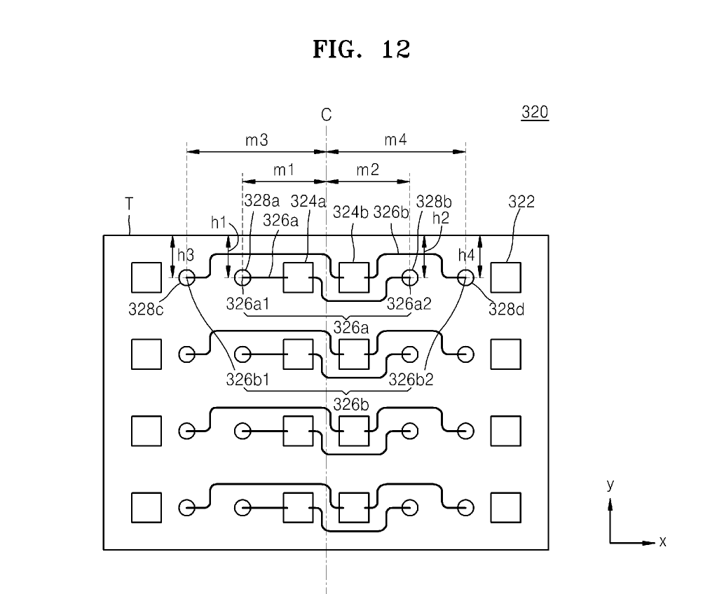

FIG. 12 is a plan view illustrating an active surface of a first semiconductor chip 320 according to an example embodiment. This example embodiment relates to a structure of a mirror-type semiconductor chip. Because a second semiconductor chip (not shown) flip-chip bonded to the first semiconductor chip 320 has the same structure as the first semiconductor chip 320, the drawing on the active surface of the second semiconductor chip is omitted.

Referring to FIG. 12, the first semiconductor chip 320 includes a first bonding pad 324a on an active surface, the center line C of which extends in the first direction y of the first semiconductor chip 320, a first rewire 326a including the first and second connection regions 326a1 and 326a2 electrically connected to the first bonding pad 324a, each of the first and second connection regions 326a1 and 326a2 being disposed at the same distance from the center line C to face each other in the second direction x (which is perpendicular to the first direction y), a second bonding pad 324b on the active surface, a second rewire 326b including the third and fourth connection regions 326b1 and 326b2 electrically connected to the second bonding pad 324b, each of the third and fourth connection regions 326b1 and 326b2 being disposed at the same distance from the center line C to face each other in the second direction x, first to fourth bump regions 328a, 328b, 328c, and 328d respectively formed in the first to fourth connections regions 326a1, 326a2, 326b1, and 326b2, and a third bonding pad 322.

Additionally, the first to fourth connections regions 326a1, 326a2, 326b1, and 326b2 may be spaced apart from each other in the second direction x.

The first and second bonding pads 324a and 324b may be electrically connected to a bonding pad of another semiconductor chip (not shown) to be mounted on the first semiconductor chip 320, and the third bonding pad 322 may be electrically connected to a substrate, e.g., through a bonding wire.

The distances from the center line C to each of the first bump 328a and a corresponding second bump 328b may be the same, that is, m1=m2, and the distances from the upper T of the first semiconductor chip 320 to a frontmost first bump 328a and a corresponding second bump 328b may be the same, that is, h1=h2.

Additionally, the distances from the center line C to each of the third bump 328c and a corresponding fourth bump 328d may be the same, that is, m3=m4, and the distances from the upper T of the first semiconductor chip 320 to a frontmost third bump 328c and a corresponding fourth bump 328d are the same, that is, h3=h4.

Because the first to fourth connection regions 326a1, 326a2, 326b1, and 326b2 where the first and second rewires 326a and 326b and the first to fourth bumps 328a, 328b, 328c, and 328d of each of a plurality of semiconductor chip areas on a wafer are disposed at same positions, a mirror-type semiconductor package may be implemented by using the plurality of semiconductor chips separated from the same wafer.

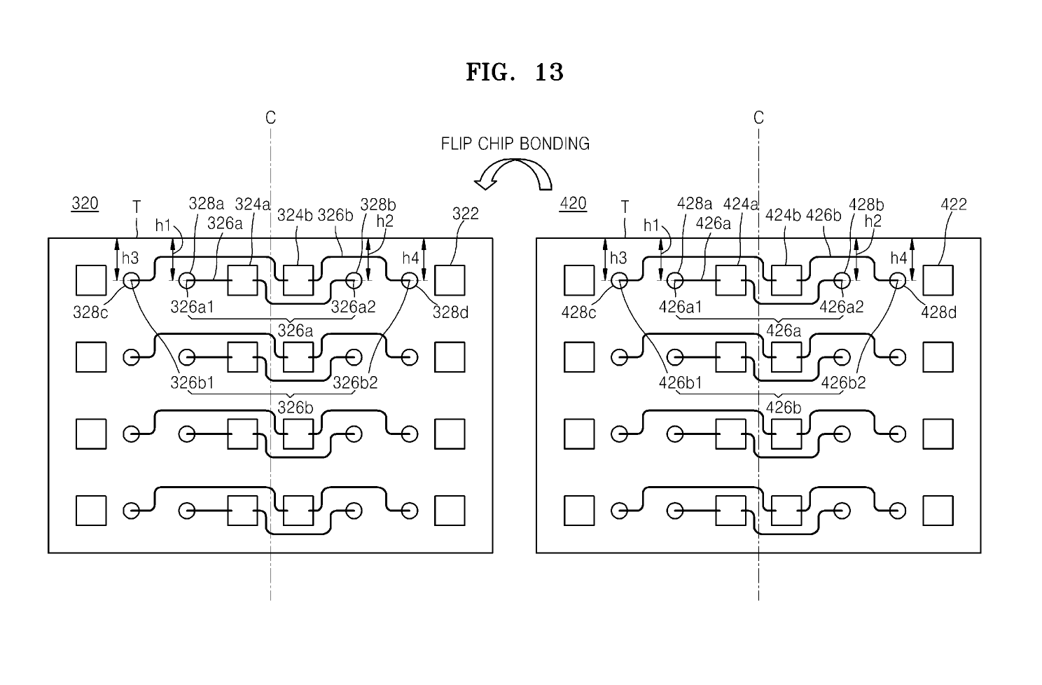

FIG. 13 shows flip-chip bonding of two semiconductor chips of FIG. 12 together. In FIG. 13, the first semiconductor chip 320 has the same structure as the second semiconductor chip 420. For example, in relation to and, the first and second bonding pads 324a and 324b, the first and second rewires 326a and 326b, and the first to fourth bumps 328a, 328b, 328c, and 328d of the first semiconductor chip 320, may be respectively formed at the same positions as third and fourth bonding pads 424a, and 424b, third and fourth rewires 426a and 426b, and the fifth to eighth bumps 428a, 428b, 428c, and 428d of the second semiconductor chip 420, as described above with reference to FIG. 12.

Referring to FIG. 13, by using a flip-chip bonding method, the first bump 328a and the second bump 328b of the first semiconductor chip 320 may be respectively connected to the sixth bump 428b and the fifth bump 428a of the second semiconductor chip 420, and the third bump 328c and the fourth bump 328d of the first semiconductor chip 320 may be respectively connected to the eighth bump 428d and the seventh bump 428c of the second semiconductor chip 420.

As mentioned above, the first to fourth rewires 326a, 326b, 426a, 426b extending from the first to fourth bonding pads 324a, 324b, 424a, and 424b may be formed and the first to eighth bumps 328a, 328b, 328c, 328d, 428a, 428b, 428c, and 428d may be formed on the first to eighth connection regions 326a1, 326a2, 326b1, 326b2, 426a1, 426a2, 426b1, and 426b2 of the first to fourth rewires 326a, 326b, 426a, and 426b, thereby forming a mirror-type semiconductor package through flip-chip bonding of the first semiconductor chip 320 and the second semiconductor chip 420.

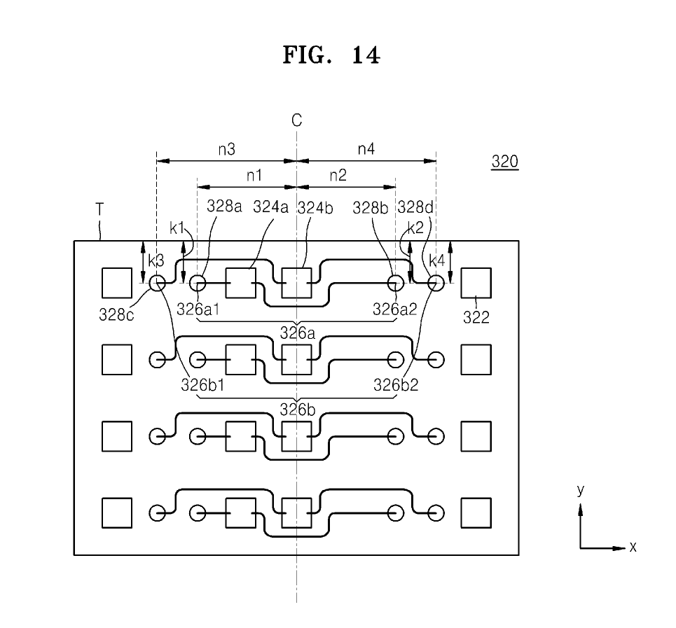

FIG. 14 is a plan view illustrating an active surface of a first semiconductor chip according to an example embodiment. Compared to FIG. 12, one of the first and second bonding pads 324a and 324b of FIG. 14 may be disposed toward the left and is spaced a desired (alternatively, predetermined) distance apart from the center line C extending in the first direction y of the active surface of the semiconductor chip 320.

Referring to FIG. 14, even when one of the first and second bonding pads 324a and 324b may be spaced a predetermined distance apart from the center line C of the active surface of the first semiconductor chip 320, a mirror-type semiconductor chip may be manufactured by controlling the positions of the first rewire 326a including the first and second connection regions 326a1 and 326a2 and the second rewire 326b including the third and fourth connection regions 326b1 and 326b2.

For this, the distances from the center line C to each of the first bump 328a and a corresponding second bump 328b may be the same, that is, n1=n2, and the distances from the upper T of the first semiconductor chip 320 to a frontmost first bump 328a and a corresponding second bump 328b may be the same, that is, k1=k2.

Additionally, the distances from the center line C to each of the third bump 328c and a corresponding fourth bump 328d may be the same, that is, n1=n2, and the distances from the upper T of the first semiconductor chip 320 to a frontmost third bump 328c and a corresponding fourth bump 328d may be the same, that is, k3=k4.

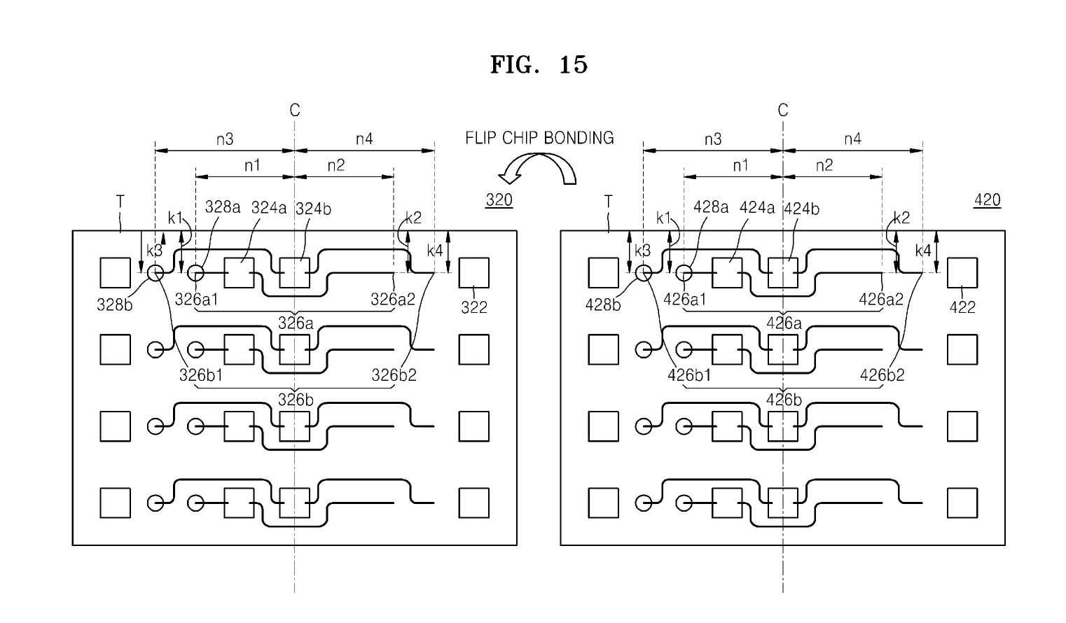

FIG. 15 shows flip-chip bonding between a first semiconductor chip and a second semiconductor chip according to an example embodiment. In FIG. 15, the first semiconductor chip 320 may have the same structure as the second semiconductor chip 420. For example, the first and second bonding pads 324a and 324b, and the first and second rewires 326a and 326b of the first semiconductor chip 320 may be respectively formed at the same positions as the third and fourth bonding pads 424a, and 424b and the third and fourth rewires 426a, and 426b of the second semiconductor chip 420, as described above with reference to FIG. 14.

Referring to FIG. 15, the first bump 328a of the first semiconductor chip 320 may be formed at the first connection region 326a of the first rewire 326a and the second bump 328b of the first semiconductor chip 320 may be formed at the third connection region 326b1 of the second rewire 326b.

Additionally, the third bump 428a of the second semiconductor chip 420 may be formed in the fifth connection region 426a1 of the third rewire 426a and the fourth bump 428b of the second semiconductor chip 420 may be formed in the seventh connection region 426b1 of the fourth rewire 426b.

The first and second semiconductor chips 320 and 420 may be flip-chip bonded to each other. Also, the first and second bumps 328a and 328b of the first semiconductor chip 320 may respectively contact the sixth connection region 426a2 of the first rewire 426a and the eighth connection region 426b2 of the fourth rewire 426b in the second semiconductor chip 420.

Additionally, the third bump 428a and the fourth bump 428b of the second semiconductor chip 420 may respectively contact the second connection region 326a2 of the first rewire 326a and the fourth connection region 326b2 of the second rewire 326b in the first semiconductor chip 320.

Accordingly, the first and second semiconductor chips 320 and 420 may be electrically connected to each other by using the first and second bumps 328a and 328b at some positions, and by using the third and fourth bumps 428a and 428b at the other positions, thereby resulting in one bump layer in effect.

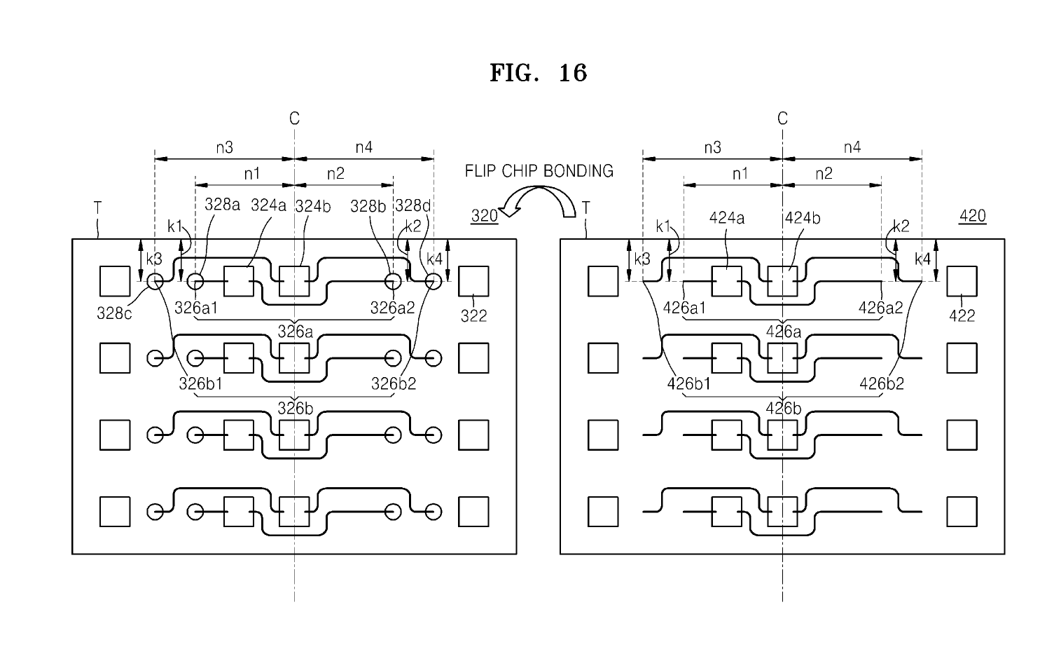

FIG. 16 shows flip-chip bonding between a first semiconductor chip and a second semiconductor chip according to an example embodiment. In FIG. 16, the first semiconductor chip 320 has the same structure as the second semiconductor chip 420. For example, the first and second bonding pads 324a and 324b, and the first and second rewires 326a and 326b of the first semiconductor chip 320 may be respectively formed at the same positions as the third and fourth bonding pads 424a and 424b, and the third and fourth rewires 426a, and 426b of the second semiconductor chip 420. Because this is described above with reference to FIG. 14, their detailed descriptions are omitted.

Referring to FIG. 16, the first and second bumps 328a and 328b of the first semiconductor chip 320 may be formed respectively in the first and second connection regions 326a1 and 326a2 of the first rewire 326a, and the third and fourth bumps 328c and 328d of the first semiconductor chip 320 may be formed respectively in the third and fourth connection regions 326b1 and 326b2 of the second rewire 326b.

Additionally, no bump may be formed on the first and second rewires 426a and 426b of the second semiconductor chip 420.

The first and second semiconductor chips 320 and 420 may be flip-chip bonded to each other. Also, the first and second bumps 328a and 328b of the first semiconductor chip 320 may respectively contact the sixth and fifth connection region 426a2 and 426a1 of the third rewire 426a in the second semiconductor chip 420, and the third and fourth bumps 328c and 328d of the first semiconductor chip 320 may respectively contact the eighth and seventh connection regions 426b2 and 426b1 of the fourth rewire 426b in the second semiconductor chip 420.

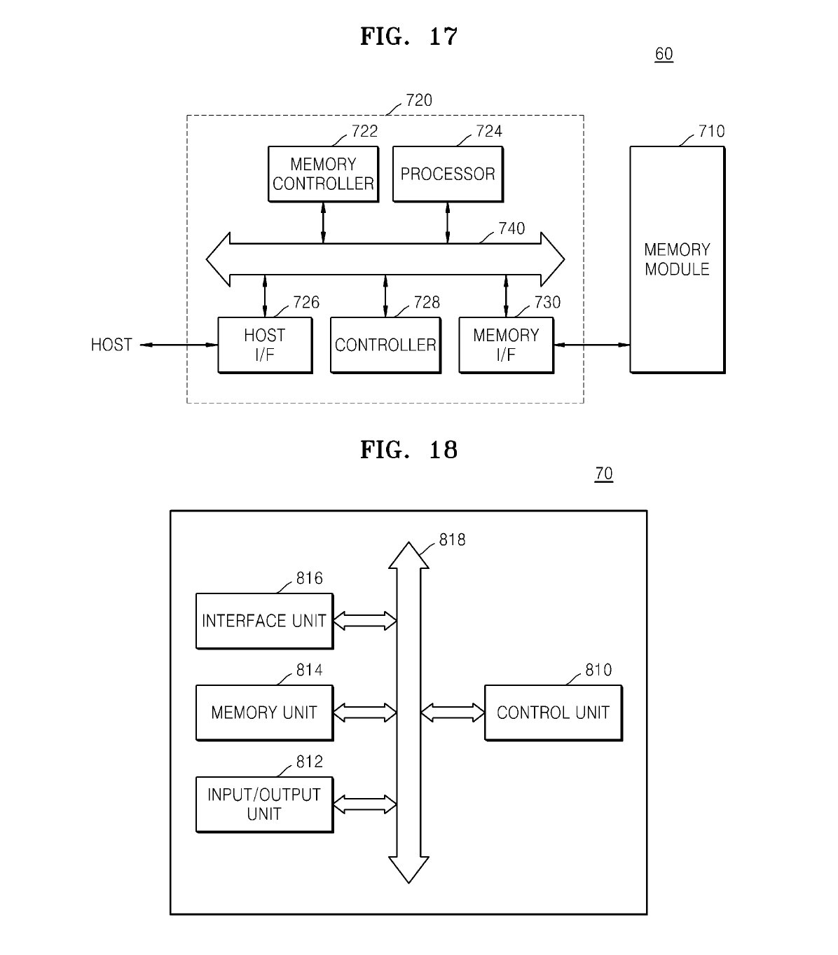

FIG. 17 is a block diagram illustrating a memory card 60 including a semiconductor package according to an example embodiment.

A memory card 60 includes a controller module 720 for generating commands and address signals C/A, and a memory module 710, e.g., a flash memory including at least one flash memory device. The controller module 720 may include a host interface 726 for transmitting/receiving command and address signals to/from a host, and a memory interface 730 for transmitting/receiving command and address signals to/from the memory module 710. The host interface 726, a controller 728, and the memory interface 730 may communicate with the memory controller 722, e.g., SRAM, and a processor 724, e.g., a central processing unit (CPU) via a common bus 740.

The memory module 710 may receive command and address signals from the memory controller 722, stores data in at least one memory device on the memory module 710 in response to the command and address signals, and searches for data from the at least one memory device. Each memory device includes a plurality of addressable memory cells and a decoder for receiving command and address signals and generating a row signal and a column signal to access at least one of addressable memory cells during a programming and reading operation.

At least one of the components of the memory card 60 including the memory controller 722, electronic devices 722, 724, 726, 728, and 730 in the controller module 720, and the memory module 710 may include a semiconductor package according to example embodiments.

FIG. 18 is a view illustrating a system 70 according to an example embodiment.

Referring to FIG. 18, the system 70 may include a control unit 810, an input/output unit 812, a memory unit 814, and an interface unit 816.

The system 70 may be a mobile system, or a system for transmitting/receiving information. The mobile system may include a PDA, a portable computer, a web tablet, a wireless phone, a mobile phone), a digital music player, or a memory card.

The control unit 810 may execute a program and controls the system 70. The control unit 810 may be a microprocessor, a digital signal processor, a micro controller, or a device similar thereto. The control unit 810 may include a semiconductor package according to one of example embodiments.

The input/output unit 812 may input and/or output data or instructions. The system 70 may be connected to an external device such as a personal computer or a network by using the input/output unit 812 so as to exchange data with the external device. The input/output device 812 may be a keypad, a keyboard, or a display.

The memory unit 814 may store code and/or data for an operation of the control unit 810, and/or may store data processed by the control unit 810. The memory unit 814 may include a semiconductor package according to one of example embodiments.

The interface unit 816 may be a data transmission path between the system 70 and another external device. The control unit 810, the input/output unit 812, the memory unit 814, and the interface unit 816 may communicate with each other via the bus 818. For example, the system 70 may be used for a mobile phone, an MP3 player, a navigation system, a portable multimedia player (PMP), a solid state disk (SSD), or household appliances.

While the inventive concepts has been particularly shown and described with reference to example embodiments thereof, it will be understood that various changes in form and details may be made therein without departing from the spirit and scope of the following claims.

What is claimed is:

1. A semiconductor package comprising:
a lower semiconductor chip; and
an upper semiconductor chip flip-chip bonded on the lower semiconductor chip, each of the lower and upper semiconductor chips including,
a first bonding pad on an active surface, the active surface having a center line extending in a first direction; and
a first rewire electrically connected to the first bonding pad, the first rewire having first and second connection regions, the first and second connection regions facing each other and disposed at a first distance from the center line in a second direction, the second direction being perpendicular to the first direction.

2. The semiconductor package of claim 1, wherein the first connection region and the second connection region of the lower semiconductor chip respectively face the second connection region and the first connection region of the upper semiconductor chip, are respectively electrically connected to each other through a bump.

3. The semiconductor package of claim 1, wherein each of the lower and upper semiconductor chips further comprises:
a second bonding pad on the active surface; and
a second rewire electrically connected to the second bonding pad, the second rewire including third and fourth connection regions, the third and fourth connection regions facing each other and disposed at a second distance from the center line in the second direction,
wherein the first to fourth connection regions are spaced apart from each other in the second direction.

4. The semiconductor package of claim 3, wherein
the lower semiconductor chip further comprises a third bonding pad, the third bonding pad is electrically connected to the substrate through a bonding wire.

5. The semiconductor package of claim 3, wherein
the first connection region and the second connection region of the lower semiconductor chip respectively face the second connection region and the first connection region of the upper semiconductor chip; and
the third connection region and the fourth connection region of the lower semiconductor chip respectively face the fourth connection region and the third connection region of the upper semiconductor chip.

6. The semiconductor package of claim 3, further comprising:
first to fourth bumps respectively on the first to fourth connection regions of the lower semiconductor chip, wherein
the first and second bumps respectively contact the second and first connection regions of the upper semiconductor chip; and
the third and fourth bumps respectively contact the fourth and third connection regions of the upper semiconductor chip.

7. The semiconductor package of claim 3, further comprising:
first and second bumps respectively on the first and third connection regions of the lower semiconductor chip; and
third and fourth bumps respectively on the first and third connection regions of the upper semiconductor chip,
wherein the first and second bumps respectively contact the second and fourth connection regions of the upper semiconductor chip; and
the third and fourth bumps respectively contact the second and fourth connection regions of the lower semiconductor chip.

8. The semiconductor package of claim 3, further comprising:
first to fourth bumps respectively on the first to fourth connection regions of the lower semiconductor chip; and
fifth to eighth bumps respectively on the first to fourth connection regions of the upper semiconductor chip,
wherein the first, second, third, and fourth bumps respectively contact the sixth, fifth, eighth, and seventh bumps.

9. A semiconductor chip comprising:
a first bonding pad on an active surface of the semiconductor chip, the active surface having a center line extending in a first direction; and
a first rewire electrically connected to the first bonding pad, the first rewire including first and second connection regions, the first and second connection regions facing each other and disposed at a first distance from the center line in a second direction, the second direction being perpendicular to the first direction.

10. The semiconductor chip of claim 9, further comprising a bump formed at at least one of the first connection region and the second connection region.

11. The semiconductor chip of claim 9, wherein the first bonding pad is disposed on the center line of the active surface.

12. The semiconductor chip of claim 9, wherein the first bonding pad is spaced a distance apart from the center line of the active surface.

13. The semiconductor chip of claim 9, further comprising:
a second bonding pad on the active surface; and
a second rewire electrically connected to the second bonding pad, the second rewire including third and fourth connection regions, the third and fourth connection regions facing each other and disposed at a second distance from the center line in the second direction,
wherein the first to fourth connection regions are spaced apart from each other in the second direction.

14. The semiconductor chip of claim 9, further comprising a bump at at least one of the third connection region and the fourth connection region.

15. The semiconductor chip of claim 9, further comprising a third bonding pad on the active surface, the third bonding pad is electrically connected to a substrate.

16. A semiconductor package comprising:
a first semiconductor chip on a substrate;
a second semiconductor chip flip-chip bonded on the first semiconductor chip, each of the first and second semiconductor chips including,
at least one first bonding pad provided in a first direction, and
at least one first rewire extending from the at least one first bonding pad in a second direction, the second direction being perpendicular to the first direction, the at least one first rewire having first and second connection regions, the first and second connection regions being opposite to each other and being at a first distance with respect to a center line of the semiconductor chip, the center line defined in the first direction; and
a plurality of connection structures on at least one of the connection regions, the connection structures configured to electrically connect the second semiconductor chip to the first semiconductor chip.

17. The semiconductor package of claim 16, wherein the connection structures are provided on the first and second connection regions of both of the first and second semiconductor chips.

18. The semiconductor package of claim 16, wherein the connection structures are provided on one of the first and second connection regions of the first and second semiconductor chips.

19. The semiconductor package of claim 16, wherein the connection structures are provided on the first and second connection regions of one of the first and second semiconductor chips.

20. The semiconductor package of claim 16, wherein the first and second semiconductor chips further include,
at least one second bonding pad provided in the first direction, each of the at least one second bonding pad paired with a corresponding first bonding pad, and
at least one second rewire extending from the at least one second bonding pad in the second direction, the at least one second rewire having third and fourth connection regions, the third and fourth connection regions being opposite to each other and being at a second distance with respect to the center line.
